(19) United States
(12) Patent Application Publication
(10) Pub. No.: US 2024/0178138 A1
(43) Pub. Date: May 30, 2024

(54) SEMICONDUCTOR DEVICE

(71) Applicant: SAMSUNG ELECTRONICS CO., LTD., Suwon-si (KR)

(72) Inventors: Yong Jin SHIN, Suwon-si (KR); Dong Woo KIM, Suwon-si (KR); Mun Jun KIM, Suwon-si (KR); Jun Kwan KIM, Suwon-si (KR); On Yu BAE, Suwon-si (KR); Kyoung Min WOO, Suwon-si (KR)

(21) Appl. No.: 18/378,182

(22) Filed: Oct. 10, 2023

(30) Foreign Application Priority Data
Nov. 29, 2022 (KR) 10-2022-0162693

(51) Int. Cl. H01L 23/528; H01L 21/768; H01L 23/532

(52) U.S. Cl. CPC H01L 23/528; H01L 21/76832; H01L 21/76841; H01L 23/53223; H01L 28/90

(57) ABSTRACT

A semiconductor device includes a substrate having a cell region and a peripheral region surrounding the cell region, a lower electrode extending in a vertical direction on the cell region of the substrate, an upper electrode surrounding a sidewall and a top surface of the lower electrode, a capacitor dielectric layer disposed between the lower electrode and the upper electrode, a first barrier layer disposed on the upper electrode, the first barrier layer in contact with each of a sidewall and a top surface of the upper electrode, a first interlayer insulating layer covering the first barrier layer, the first interlayer insulating layer including a material different from the first barrier layer, and a first contact penetrating through the first barrier layer and the first interlayer insulating layer in the vertical direction, the first contact connected to the upper electrode.

### CROSS-REFERENCE TO RELATED APPLICATION

This application claims priority from Korean Patent Application No. 10-2022-0162693, filed on Nov. 29, 2022, in the Korean Intellectual Property Office, and all the benefits accruing therefrom under 35 U.S.C. 119, the contents of which in its entirety are herein incorporated by reference.

### BACKGROUND

### 1. Field

The present disclosure relates to a semiconductor device.

### 2. Description of the Related Art

As semiconductor elements are increasingly highly integrated, discrete circuit patterns are becoming more miniaturized to implement more semiconductor elements on the same area. That is, design rules for components of the semiconductor elements are decreasing. As a dynamic random access memory (DRAM) device is also integrated, an amount of charges charged in the capacitor is steadily decreasing. For example, a buried channel array transistor (BCAT) may be implemented in the DRAM device to overcome a short channel effect by including a gate electrode buried in a trench. Therefore, research is being conducted to increase the amount of charge stored in the capacitor and to improve leakage characteristics.

### SUMMARY

According to some embodiments of the present disclosure, there is provided a semiconductor device, including a substrate including a cell region and a peripheral region surrounding the cell region, a lower electrode extending in a vertical direction on the cell region of the substrate, an upper electrode surrounding a sidewall and a top surface of the lower electrode, a capacitor dielectric layer disposed between the lower electrode and the upper electrode, a first barrier layer disposed on the upper electrode, the first barrier layer in contact with each of a sidewall and a top surface of the upper electrode, a first interlayer insulating layer covering the first barrier layer, the first interlayer insulating layer including a material different from the first barrier layer, and a first contact penetrating through the first barrier layer and the first interlayer insulating layer in the vertical direction, the first contact connected to the upper electrode.

According to some embodiments of the present disclosure, there is provided a semiconductor device, including a substrate including a cell region and a peripheral region surrounding the cell region, a lower electrode extending in a vertical direction on the cell region of the substrate, an upper electrode surrounding a sidewall and a top surface of the lower electrode, a capacitor dielectric layer disposed between the lower electrode and the upper electrode, a first barrier layer disposed on the upper electrode, the first barrier layer in contact with each of a sidewall and a top surface of the upper electrode, the first barrier layer conformally formed, the first barrier layer including an aluminum element, and an etch stop layer disposed between the substrate and the first barrier layer, the etch stop layer surrounding a portion of the sidewall of the lower electrode, the etch stop layer in contact with the first barrier layer on the peripheral region of the substrate.

According to some embodiments of the present disclosure, there is provided a semiconductor device, including a substrate including a cell region and a peripheral region surrounding the cell region, a lower electrode extending in a vertical direction on the cell region of the substrate, an upper electrode surrounding a sidewall and a top surface of the lower electrode, a capacitor dielectric layer disposed between the lower electrode and the upper electrode, a first barrier layer disposed on the upper electrode, the first barrier layer in contact with each of a sidewall and a top surface of the upper electrode, the first barrier layer conformally formed, the first barrier layer including at least one of aluminum oxide (Al₂O₃) and aluminum nitride (AlN), a first interlayer insulating layer covering the first barrier layer, the first interlayer insulating layer including a material different from the first barrier layer, an etch stop layer disposed between the substrate and the first barrier layer, the etch stop layer surrounding a portion of the sidewall of the lower electrode, the etch stop layer in contact with the first barrier layer on the peripheral region of the substrate, a first contact penetrating through the first barrier layer and the first interlayer insulating layer in the vertical direction, the first contact connected to the upper electrode, and a second contact penetrating through the first barrier layer and the first interlayer insulating layer in the vertical direction on the peripheral region of the substrate, the second contact spaced apart from the upper electrode in a horizontal direction, wherein a top surface of the first interlayer insulating layer, a top surface of the first contact, and a top surface of the second contact are each formed on the same plane.

### BRIEF DESCRIPTION OF THE DRAWINGS

Features will become apparent to those of skill in the art by describing in detail exemplary embodiments with reference to the attached drawings, in which:

FIG. 1 is a schematic layout view for describing a cell region of a semiconductor device according to some exemplary embodiments of the present disclosure;

FIG. 2 is a cross-sectional view taken along line A-A′ of FIG. 1;

FIG. 3 is an enlarged view of region R1 of FIG. 2;

FIGS. 4 to 12 are views of stages in a method of manufacturing a semiconductor device according to some exemplary embodiments of the present disclosure;

FIG. 13 is a cross-sectional view for describing a semiconductor device according to some other exemplary embodiments of the present disclosure;

FIG. 14 is an enlarged view of region R2 of FIG. 13;

FIG. 15 is a cross-sectional view for describing a semiconductor device according to still other exemplary embodiments;

FIG. 16 is an enlarged view of region R3 of FIG. 15;

FIG. 17 is a cross-sectional view for describing a semiconductor device according to yet other exemplary embodiments of the present disclosure;

FIG. 18 is an enlarged view of region R4 of FIG. 17;

FIG. 19 is a cross-sectional view for describing a semiconductor device according to still other exemplary embodiments;

FIG. 20 is an enlarged view of region R5 of FIG. 19;

FIG. 21 is a cross-sectional view for describing a semiconductor device according to yet other exemplary embodiments of the present disclosure;

FIG. 22 is an enlarged view of region R6 of FIG. 21;

FIG. 23 is a cross-sectional view for describing a semiconductor device according to still other exemplary embodiments of the present disclosure;

FIG. 24 is an enlarged view of region R7 of FIG. 23; and

FIG. 25 is a cross-sectional view for describing a semiconductor device according to yet other exemplary embodiments.

### DETAILED DESCRIPTION

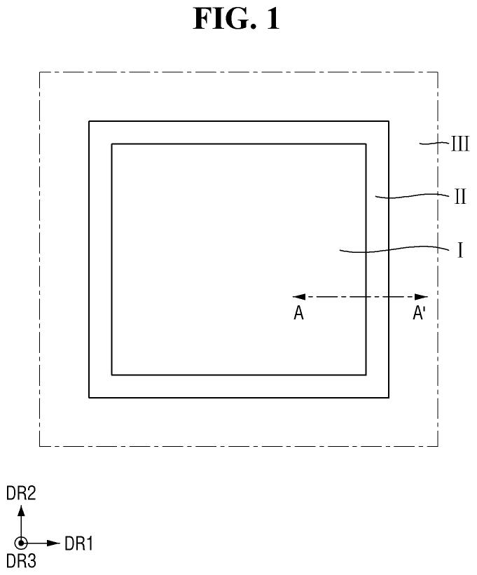

Hereinafter, a semiconductor device according to some exemplary embodiments of the present disclosure will be described with reference to FIGS. 1 to 3.

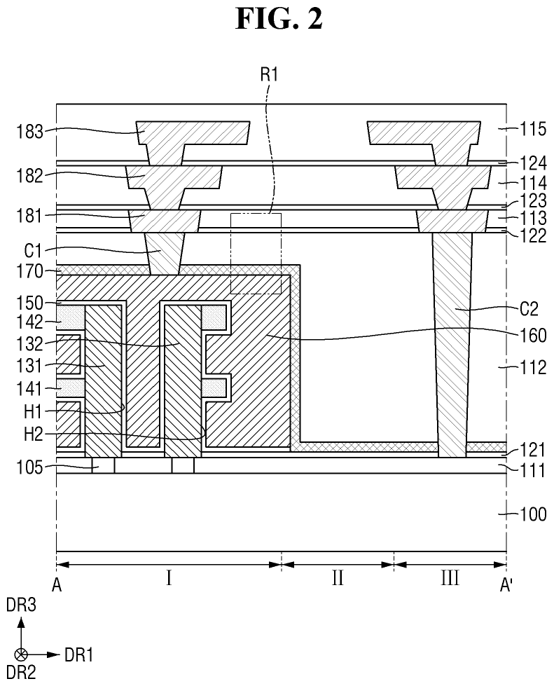

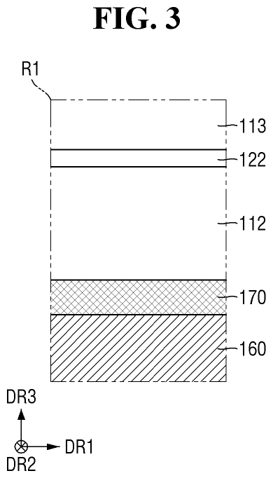

FIG. 1 is a schematic layout view of a cell region of a semiconductor device according to some exemplary embodiments of the present disclosure. FIG. 2 is a cross-sectional view along line A-A′ of FIG. 1. FIG. 3 is an enlarged view of region R1 of FIG. 2.

Referring to FIGS. 1 to 3, a semiconductor device according to some exemplary embodiments of the present disclosure may include a substrate 100, a contact plug 105, first to fifth interlayer insulating layers 111, 112, 113, 114, and 115, first to fourth etch stop layers 121, 122, 123, and 124, first and second lower electrodes 131 and 132, first and second supporter patterns 141 and 142, capacitor dielectric layer 150, an upper electrode 160, a first barrier layer 170, first and second contacts C1 and C2, and first to third wiring patterns 181, 182, and 183.

For example, the substrate 100 may include bulk silicon or silicon-on-insulator (SOI). In another example, the substrate 100 may include a silicon substrate, or may include another material, e.g., silicon germanium, silicon germanium on insulator (SGOI), indium antimonide, lead tellurium compound, indium arsenide, indium phosphide, gallium arsenide, or gallium antimonide.

Although not illustrated, word lines and bit lines may be disposed inside the substrate 100. A unit active region and an element separation region may be formed on the substrate 100. For example, two transistors may be formed in one unit active region.

Hereinafter, each of a first horizontal direction DR1 and a second horizontal direction DR2 is defined as a direction parallel to a top surface of the substrate 100, and the second horizontal direction DR2 is defined as a direction perpendicular to the first horizontal direction DR1. In addition, a vertical direction DR3 is a direction perpendicular to each of the first and second horizontal directions DR1 and DR2, and is defined as a direction perpendicular to the top surface of the substrate 100.

The substrate 100 may include a cell region I, a separation region II, and a peripheral region III. In a plane defined by the first horizontal direction DR1 and the second horizontal direction DR2, the peripheral region III may surround the cell region I. The separation region II may separate the cell region I and the peripheral region III. That is, the separation region II may be formed along a boundary between the cell region I and the peripheral region III.

A first interlayer insulating layer 111 may be formed on the substrate 100. The first interlayer insulating layer 111 may include, e.g., at least one of silicon oxide (SiO₂), silicon nitride (SiN), silicon oxynitride (SiON), and a low-k material. For example, the first interlayer insulating layer 111 may be a single layer or multiple layers.

The contact plug 105 may be disposed in the first interlayer insulating layer 111. The contact plug 105 may penetrate through the first interlayer insulating layer 111 in the vertical direction DR3. The contact plug 105 may be electrically connected to source/drain regions formed in the substrate 100. The contact plug 105 may include a conductive material. The contact plug 105 may include, e.g., at least one of polycrystalline silicon, a metal silicide compound, conductive metal nitride, and a metal (e.g., non-compound metal).

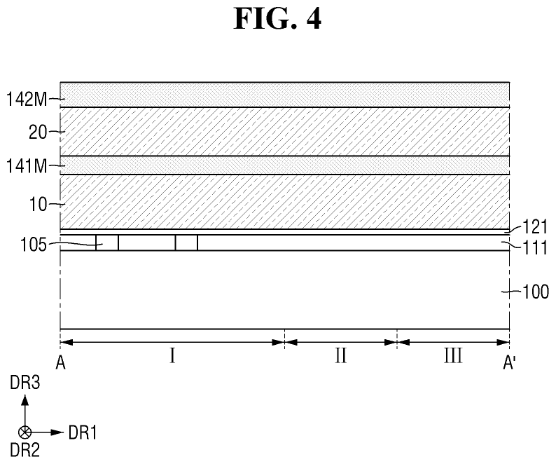

The first etch stop layer 121 may be disposed on the first interlayer insulating layer 111. The first etch stop layer 121 may include a material having an etch selectivity with respect to a first molding layer (10 in FIG. 4) and a second molding layer (20 in FIG. 4) including oxide. The first etch stop layer 121 may include, e.g., at least one of silicon nitride (SiN), silicon carbon nitride (SiCN), silicon boron nitride (SiBN), silicon carbonate (SiCO), silicon oxynitride (SiON), silicon oxide (SiO), and silicon oxycarbonitride (SiOCN).

The first supporter pattern 141 may be disposed on the cell region I of the substrate 100. The first supporter pattern 141 may be spaced apart from the first etch stop layer 121 in the vertical direction DR3 on the first etch stop layer 121. The second supporter pattern 142 may be disposed on the cell region I of the substrate 100. The second supporter pattern 142 may be spaced apart from the first supporter pattern 141 in the vertical direction DR3 on the first supporter pattern 141.

Each of the first supporter pattern 141 and the second supporter pattern 142 may surround a portion of a sidewall of each of the first and second lower electrodes 131 and 132 to be described later. Each of the first supporter pattern 141 and the second supporter pattern 142 may be in, e.g., direct, contact with a portion of the sidewall of each of the first and second lower electrodes 131 and 132 to be described later. For example, a thickness of the second supporter pattern 142 in the vertical direction DR3 may be greater than a thickness of the first supporter pattern 141 in the vertical direction DR3.

Each of the first supporter pattern 141 and the second supporter pattern 142 may include, e.g., at least one of silicon oxynitride (SiON), silicon nitride (SiN), silicon carbon nitride (SiCN), and tantalum oxide (TaO). For example, the first supporter pattern 141 and the second supporter pattern 142 may include the same material. In another example, the first supporter pattern 141 and the second supporter pattern 142 may include different materials.

A plurality of lower electrode holes may be formed to be spaced apart from each other on the cell region I of the substrate 100. Each of the plurality of lower electrode holes may extend in the vertical direction DR3. For example, each of a first lower electrode hole H1 and a second lower electrode hole H2 may extend on the contact plug 105 in the vertical direction DR3. For example, each of the first lower electrode hole H1 and the second lower electrode hole H2 may extend from a top surface of the contact plug 105 to a top surface of the second supporter pattern 142. For example, the second lower electrode hole H2 may be spaced apart from the first lower electrode hole H1 in the first horizontal direction DR1.

The first lower electrode 131 may be disposed in the first lower electrode hole H1. For example, the first lower electrode 131 may completely fill the first lower electrode hole H1 on the contact plug 105. That is, the first lower electrode 131 may have a pillar shape. The first lower electrode 131 may penetrate through the first etch stop layer 121 on the contact plug 105 and extend in the vertical direction DR3. The first lower electrode 131 may be electrically connected to the contact plug 105.

The first lower electrode 131 may be in, e.g., direct, contact with each of a sidewall of the first supporter pattern 141 and a sidewall of the second supporter pattern 142. Each of the first supporter pattern 141 and the second supporter pattern 142 may surround a portion of the sidewall of the first lower electrode 131. For example, the uppermost surface of the first lower electrode 131 may be formed on the same plane as the top surface of the second supporter pattern 142, e.g., the uppermost surface of the first lower electrode 131 and the top surface of the second supporter pattern 142 may be coplanar (e.g., level) with each other.

The second lower electrode 132 may be disposed in the second lower electrode hole H2. For example, the second lower electrode 132 may be spaced apart from the first lower electrode 131 in the first horizontal direction DR1. For example, the second lower electrode 132 may completely fill the second lower electrode hole H2 on the contact plug 105. That is, the second lower electrode 132 may have a pillar shape. The second lower electrode 132 may penetrate through the first etch stop layer 121 on the contact plug 105 and extend in the vertical direction DR3. The second lower electrode 132 may be electrically connected to the contact plug 105.

The second lower electrode 132 may be in, e.g., direct, contact with each of the sidewall of the first supporter pattern 141 and the sidewall of the second supporter pattern 142. Each of the first supporter pattern 141 and the second supporter pattern 142 may surround a portion of the sidewall of the second lower electrode 132. For example, the uppermost surface of the second lower electrode 132 may be formed on the same plane as the top surface of the second supporter pattern 142, e.g., the uppermost surface of the second lower electrode 132 and the top surface of the second supporter pattern 142 may be coplanar (e.g., level) with each other.

For example, an open region may be formed between the first lower electrode 131 and the second lower electrode 132. The open region may extend from a top surface of the first etch stop layer 121 to the top surface of the second supporter pattern 142 in the vertical direction DR3. Each of the first supporter pattern 141 and the second supporter pattern 142 is not disposed in the open region.

Each of the first lower electrode 131 and the second lower electrode 132 may include, e.g., a doped semiconductor material, conductive metal nitride (e.g., titanium nitride, tantalum nitride, niobium nitride, tungsten nitride, or the like), a metal (e.g., ruthenium, iridium, titanium, tantalum, or the like), conductive metal oxide (e.g., iridium oxide, niobium oxide, or the like), and the like.

The capacitor dielectric layer 150 may be conformally, e.g., and continuously, disposed along a surface of each of the first etch stop layer 121, the first supporter pattern 141, the second supporter pattern 142, the first lower electrode 131, and the second lower electrode 132 on the cell region I of the substrate 100. For example, a portion of the capacitor dielectric layer 150 may also be disposed on the separation region II of the substrate 100. For example, the capacitor dielectric layer 150 is not disposed between each of the first and second lower electrodes 131 and 132 and the first supporter pattern 141 (e.g., so each of the first and second lower electrodes 131 and 132 may be in direct contact with the first supporter pattern 141). In addition, the capacitor dielectric layer 150 is not disposed between each of the first and second lower electrodes 131 and 132 and the second supporter pattern 142 (e.g., so each of the first and second lower electrodes 131 and 132 may be in direct contact with the second supporter pattern 142).

The capacitor dielectric layer 150 may include, e.g., at least one of silicon oxide (SiO₂), silicon nitride (SiN), silicon oxynitride (SiON), and a high-k material. The high-k material may include, e.g., at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The upper electrode 160 may be disposed on the capacitor dielectric layer 150 on the cell region I of the substrate 100. For example, a portion of the upper electrode 160 may also be disposed on the separation region II of the substrate 100. For example, the upper electrode 160 may surround each of the first lower electrode 131, the second lower electrode 132, the first supporter pattern 141, and the second supporter pattern 142 on the capacitor dielectric layer 150. For example, a sidewall of the upper electrode 160 and a sidewall of the capacitor dielectric layer 150 may be aligned in the vertical direction DR3.

For example, the upper electrode 160 may include a doped semiconductor material, conductive metal nitride (e.g., titanium nitride, tantalum nitride, niobium nitride, tungsten nitride, or the like), a metal (e.g., ruthenium, iridium, titanium, tantalum, or the like), conductive metal oxide (e.g., iridium oxide, niobium oxide, or the like), and the like.

The first barrier layer 170 may be disposed on the upper electrode 160 and the first etch stop layer 121. In detail, the first barrier layer 170 may be disposed along a sidewall (e.g., an external sidewall) and a top surface of the upper electrode 160. The first barrier layer 170 may be in, e.g., direct, contact with each of the sidewall (e.g., external sidewall) and the top surface of the upper electrode 160. In addition, the first barrier layer 170 may be disposed along the top surface of the first etch stop layer 121 on each of the separation region II and the peripheral region III of the substrate 100. The first barrier layer 170 may be in, e.g., direct, contact with the top surface of the first etch stop layer 121 on each of the separation region II and the peripheral region III. For example, the first barrier layer 170 may be conformally formed. That is, the first barrier layer 170 may be formed with a uniform thickness.

The first barrier layer 170 may include at least one of metal oxide and metal nitride. For example, the first barrier layer 170 may include an aluminum (Al) element. For example, the first barrier layer 170 may include at least one of aluminum oxide (Al₂O₃) and aluminum nitride (AlN). In some other exemplary embodiments, the first barrier layer 170 may also include metal oxynitride. For example, the first barrier layer 170 may include aluminum oxynitride (AlON).

The second interlayer insulating layer 112 may cover the first barrier layer 170 on the first barrier layer 170, e.g., the second interlayer insulating layer 112 may cover an entire upper surface and lateral surface of the first barrier layer 170. The second interlayer insulating layer 112 may be in, e.g., direct, contact with the first barrier layer 170. The second interlayer insulating layer 112 may include a material different from that of the first barrier layer 170. The second interlayer insulating layer 112 may include, e.g., at least one of silicon oxide (SiO₂), silicon nitride (SiN), silicon oxynitride (SiON), tetraethyl orthosilicate (TEOS), and a low-k material.

The first contact C1 may be disposed on the cell region I of the substrate 100. The first contact C1 may be connected to the upper electrode 160 by penetrating through the first barrier layer 170 and the second interlayer insulating layer 112 in the vertical direction DR3. The second contact C2 may be disposed on the peripheral region III of the substrate 100. For example, the second contact C2 may be spaced apart from the upper electrode 160 in the first horizontal direction DR1. The second contact C2 may penetrate through the first etch stop layer 121, the first barrier layer 170, and the second interlayer insulating layer 112 in the vertical direction DR3. For example, the second contact C2 may be connected to a wiring pattern disposed inside the first interlayer insulating layer 111.

For example, each of a top surface of the first contact C1 and a top surface of the second contact C2 may be formed on the same plane as a top surface of the second interlayer insulating layer 112, e.g., each of the top surfaces of the first and second contacts C1 and C2 may be coplanar with the top surface of the second interlayer insulating layer 112. Each of the first contact C1 and the second contact C2 may include a conductive material. Although it is illustrated in FIG. 2 that each of the first contact C1 and the second contact C2 is formed as a single film, this is merely for convenience of explanation, e.g., each of the first contact C1 and the second contact C2 may be formed as multiple films.

The second etch stop layer 122 may be disposed on the second interlayer insulating layer 112. For example, the second etch stop layer 122 may be conformally formed. The second etch stop layer 122 may include, e.g., at least one of silicon oxide, silicon nitride, silicon oxynitride, and a low-k material. The third interlayer insulating layer 113 may be disposed on the second etch stop layer 122. The third interlayer insulating layer 113 may include, e.g., at least one of silicon oxide (SiO₂), silicon nitride (SiN), silicon oxynitride (SiON), tetraethyl orthosilicate (TEOS), and a low-k material.

The first wiring pattern 181 may be disposed in each of the second etch stop layer 122 and the third interlayer insulating layer 113. For example, the first wiring pattern 181 may include a plurality of wirings spaced apart from each other in the first horizontal direction DR1 and the second horizontal direction DR2. For example, some wirings of the first wiring pattern 181 may be disposed on the first contact C1. Some wirings of the first wiring pattern 181 may be connected to the first contact C1. For example, some other wirings of the first wiring pattern 181 may be disposed on the second contact C2. Some other wirings of the first wiring pattern 181 may be connected to the second contact C2.

For example, at least a portion of a bottom surface of the first wiring pattern 181 may be in, e.g., direct, contact with the second interlayer insulating layer 112. For example, a top surface of the first wiring pattern 181 may be formed on the same plane as, e.g., coplanar or level with, a top surface of the third interlayer insulating layer 113. The first wiring pattern 181 may include a conductive material. Although it is illustrated in FIG. 2 that the first wiring pattern 181 is formed as a single film, this is merely for convenience of explanation, e.g., the first wiring pattern 181 may be formed as multiple films.

The third etch stop layer 123 may be disposed on the third interlayer insulating layer 113. For example, the third etch stop layer 123 may be conformally formed. The third etch stop layer 123 may include, e.g., at least one of silicon oxide, silicon nitride, silicon oxynitride, and a low-k material. The fourth interlayer insulating layer 114 may be disposed on the third etch stop layer 123. The fourth interlayer insulating layer 114 may include, e.g., at least one of silicon oxide (SiO₂), silicon nitride (SiN), silicon oxynitride (SiON), tetraethyl orthosilicate (TEOS), and a low-k material.

The second wiring pattern 182 may be disposed in each of the third etch stop layer 123 and the fourth interlayer insulating layer 114. For example, the second wiring pattern 182 may include a plurality of wirings spaced apart from each other in the first horizontal direction DR1 and the second horizontal direction DR2. In addition, the second wiring pattern 182 may include a plurality of vias connecting each of the plurality of wirings spaced apart from each other and the first wiring pattern 181.

For example, a top surface of the second wiring pattern 182 may be formed on the same plane as (e.g., coplanar or level with) a top surface of the fourth interlayer insulating layer 114. The second wiring pattern 182 may include a conductive material. Although it is illustrated in FIG. 2 that the second wiring pattern 182 is formed as a single film, this is merely for convenience of explanation, e.g., the second wiring pattern 182 may be formed as multiple films.

The fourth etch stop layer 124 may be disposed on the fourth interlayer insulating layer 114. For example, the fourth etch stop layer 124 may be conformally formed. The fourth etch stop layer 124 may include, e.g., at least one of silicon oxide, silicon nitride, silicon oxynitride, and a low-k material. A fifth interlayer insulating layer 115 may be disposed on the fourth etch stop layer 124. The fifth interlayer insulating layer 115 may include, e.g., at least one of silicon oxide (SiO₂), silicon nitride (SiN), silicon oxynitride (SiON), tetraethyl orthosilicate (TEOS), and a low-k material.

The third wiring pattern 183 may be disposed in each of the fourth etch stop layer 124 and the fifth interlayer insulating layer 115. For example, the third wiring pattern 183 may include a plurality of wirings spaced apart from each other in the first horizontal direction DR1 and the second horizontal direction DR2. In addition, the third wiring pattern 183 may include a plurality of vias connecting each of the plurality of wirings spaced apart from each other and the second wiring pattern 182.

For example, the fifth interlayer insulating layer 115 may cover a top surface of the third wiring pattern 183. In some other exemplary embodiments, the top surface of the third wiring pattern 183 may be formed on the same plane as (e.g., coplanar or level with) a top surface of the fifth interlayer insulating layer 115. The third wiring pattern 183 may include a conductive material. Although it is illustrated in FIG. 2 that the third wiring pattern 183 is formed as a single film, this is merely for convenience of explanation, e.g., the third wiring pattern 183 may be formed as multiple films.

The semiconductor device according to some exemplary embodiments of the present disclosure may prevent hydrogen ions present in the second interlayer insulating layer 112 from directly moving into the upper electrode 160 by disposing the first barrier layer 170 along the surface of the upper electrode 160, e.g., the first barrier layer 170 may completely separate the upper electrode 160 from the second interlayer insulating layer 112. Further, by disposing the first barrier layer 170 along the surface of the upper electrode 160 (e.g., along an entire surface of the upper electrode 160 that faces the second interlayer insulating layer 112), hydrogen ions present in the fifth interlayer insulating layer 115 may be effectively induced to move into the upper electrode 160 through the wiring patterns 181, 182, and 183 disposed on the second interlayer insulating layer 112. Accordingly, as deterioration of the wiring patterns 181, 182, and 183 is prevented, gate induced drain leakage (GIDL) characteristics may be improved.

Hereinafter, a method of manufacturing a semiconductor device according to some exemplary embodiments of the present disclosure will be described with reference to FIGS. 2 and 4 to 12.

FIGS. 4 to 12 are cross-sectional views of stages in a method of manufacturing a semiconductor device according to some exemplary embodiments of the present disclosure.

Referring to FIG. 4, the first interlayer insulating layer 111 may be formed on the substrate 100. In addition, the contact plug 105 may be formed in the first interlayer insulating layer 111. Next, the first etch stop layer 121, a first molding layer 10, a first supporter material layer 141M, a second molding layer 20, and a second supporter material layer 142M may be, e.g., sequentially, formed on the first interlayer insulating layer 111 and the contact plug 105. Each of the first supporter material layer 141M and the second supporter material layer 142M may include, e.g., at least one of silicon oxynitride (SiON), silicon nitride (SiN), silicon carbon nitride (SiCN), and tantalum oxide (TaO).

Each of the first molding layer 10 and the second molding layer 20 may include, e.g., silicon oxide (SiO₂). Each of the first molding layer 10 and the second molding layer 20 may include, e.g., flowable oxide (FOX), tonen silazen (TOSZ), undoped silica glass (USG), borosilica glass (BSG), phosphosilaca glass (PSG), borophosphosilica glass (BPSG), plasma enhanced tetra ethyl ortho silicate (PE-TEOS), fluoride silicate glass (FSG), or a combination thereof.

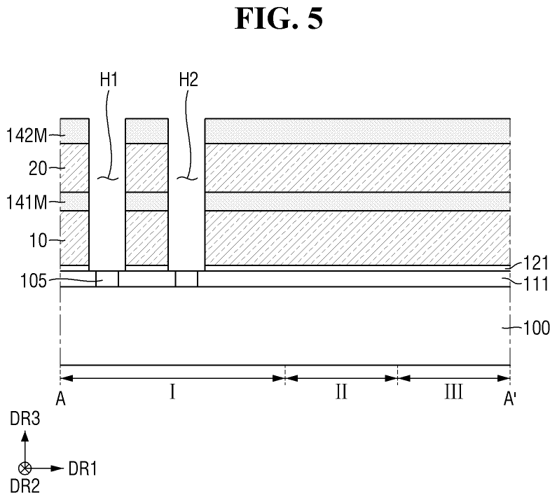

Referring to FIG. 5, the first lower electrode hole H1 and the second lower electrode hole H2 penetrating through the first etch stop layer 121, the first molding layer 10, the first supporter material layer 141M, the second molding layer 20, and the second supporter material layer 142M in the vertical direction DR3 may be formed on the cell region I of the substrate 100. For example, the second lower electrode hole H2 may be spaced apart from the first lower electrode hole H1 in the first horizontal direction DR1. The contact plug 105 may be exposed through each of the first lower electrode hole H1 and the second lower electrode hole H2.

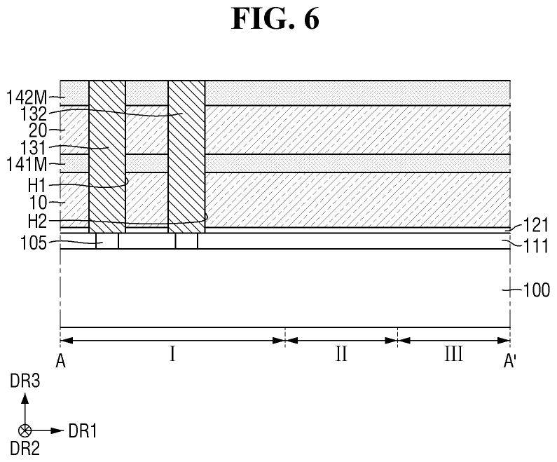

Referring to FIG. 6, the first lower electrode 131 may be formed inside the first lower electrode hole H1. For example, the first lower electrode 131 may completely fill the first lower electrode hole H1. In addition, the second lower electrode 132 may be formed inside the second lower electrode hole H2. For example, the second lower electrode 132 may completely fill the second lower electrode hole H2. That is, the second lower electrode 132 may be spaced apart from the first lower electrode 131 in the first horizontal direction DR1. For example, each of a top surface of the first lower electrode 131 and a top surface of the second lower electrode 132 may be formed on the same plane as (e.g., coplanar with) a top surface of the second supporter material layer 142M.

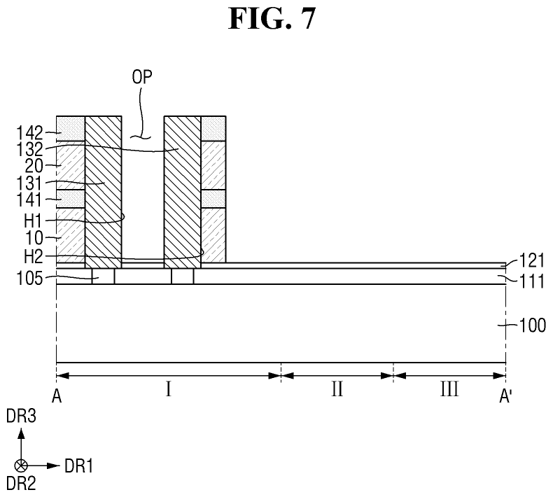

Referring to FIG. 7, an open region OP may be formed on the first etch stop layer 121 between the first lower electrode 131 and the second lower electrode 132. The open region OP may be formed by etching the first molding layer 10, the first supporter material layer (141M in FIG. 6), the second molding layer 20, and the second supporter material layer (142M in FIG. 6). In addition, the first molding layer 10, the first supporter material layer (141M in FIG. 6), the second molding layer 20, and the second supporter material layer (142M in FIG. 6) may be etched on a portion of the cell region I of the substrate 100, the separation region II of the substrate 100, and the peripheral region III of the substrate 100, respectively.

After the etching process is performed, a portion of each of the first molding layer 10, the first supporter material layer (141M in FIG. 6), the second molding layer 20, and the second supporter material layer (142M in FIG. 6) may remain on one sidewall of the second lower electrode 132. After such an etching process is performed, the first etch stop layer 121 may be exposed on the open region OP, a portion of the cell region I of the substrate 100, the separation region II of the substrate 100, and the peripheral region III of the substrate 100, respectively. The first supporter material layer (141M in FIG. 6) remaining after such an etching process is performed may be defined as the first supporter pattern 141. In addition, the second supporter material layer (142M in FIG. 6) remaining after such an etching process is performed may be defined as the second supporter pattern 142.

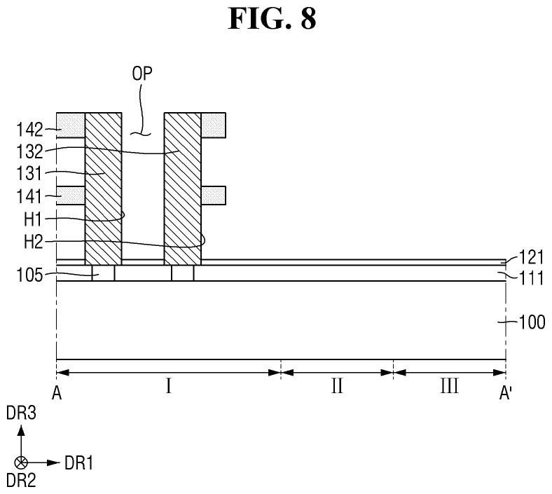

Referring to FIG. 8, each of the first molding layer (10 in FIG. 7) and the second molding layer (20 in FIG. 7) may be removed. For example, each of the first molding layer (10 in FIG. 7) and the second molding layer (20 in FIG. 7) may be etched by a wet etching process.

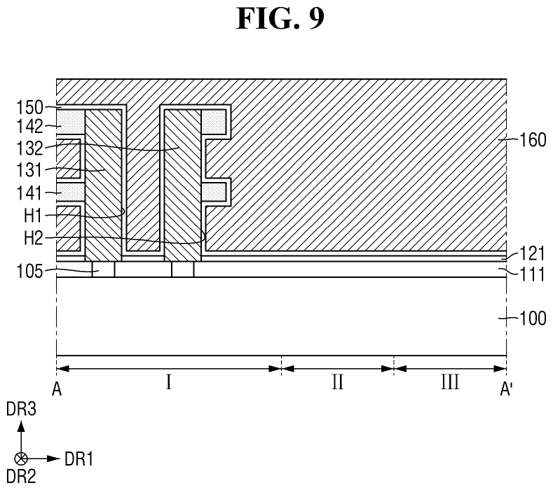

Referring to FIG. 9, the capacitor dielectric layer 150 may be formed on each of the exposed surface of the first etch stop layer 121, the exposed surface of the first lower electrode 131, the exposed surface of the second lower electrode 132, the exposed surface of the first supporter pattern 141, and the exposed surface of the second supporter pattern 142. For example, the capacitor dielectric layer 150 may be conformally formed. Next, the upper electrode 160 may be formed on the capacitor dielectric layer 150. For example, each of the capacitor dielectric layer 150 and the upper electrode 160 may be formed on the cell region I, the separation region II, and the peripheral region III of the substrate 100.

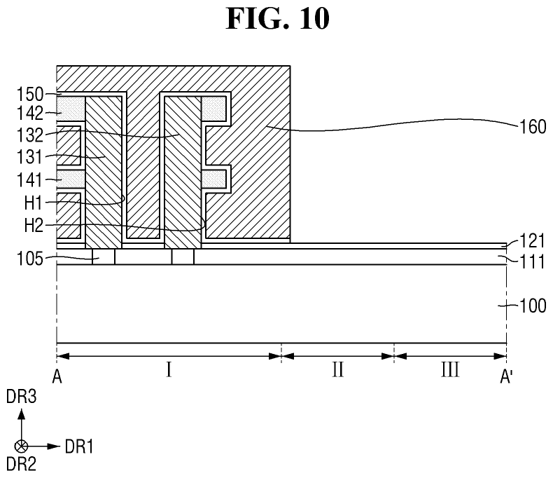

Referring to FIG. 10, the capacitor dielectric layer 150 and the upper electrode 160 may be etched on each of the separation region II and the peripheral region III of the substrate 100. As a result, the first etch stop layer 121 may be exposed on each of the separation region II and the peripheral region III of the substrate 100. Although it is illustrated in FIG. 10 that the capacitor dielectric layer 150 and the upper electrode 160 remain on the separation region II of the substrate 100, the present disclosure is not limited thereto. In some other exemplary embodiments, a portion of each of the capacitor dielectric layer 150 and the upper electrode 160 on the cell region I of the substrate 100 adjacent to the separation region II of the substrate 100 may be etched.

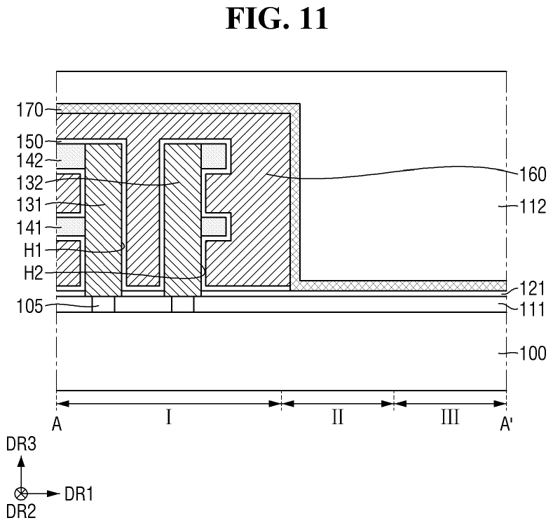

Referring to FIG. 11, the first barrier layer 170 may be formed on each of the sidewall (e.g., external sidewall) and top surface of the upper electrode 160 and the exposed top surface of the first etch stop layer 121. For example, the first barrier layer 170 may be in, e.g., direct, contact with the first etch stop layer 121 on each of the separation region II and the peripheral region III of the substrate 100. For example, the first barrier layer 170 may be conformally formed. Next, the second interlayer insulating layer 112 may be formed on the first barrier layer 170. For example, a top surface of the second interlayer insulating layer 112 may be formed to have the same height, e.g., the entire top surface of the second interlayer insulating layer 112 may be flat and parallel to the bottom of the substrate 100. For example, as illustrated in FIG. 11, a height of the top surface of the second interlayer insulating layer 112 may be at a higher level than an uppermost surface of the first barrier layer 170, relative to the bottom of the substrate 100.

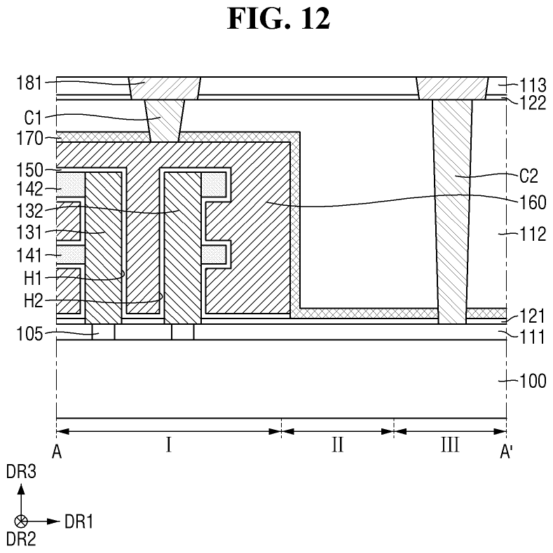

Referring to FIG. 12, the first contact C1 penetrating through the first barrier layer 170 and the second interlayer insulating layer 112 in the vertical direction DR3 and connected to the upper electrode 160 may be formed on the cell region I of the substrate 100. For example, a top surface of the first contact C1 may be formed on the same plane as (e.g., coplanar with) the top surface of the second interlayer insulating layer 112. In addition, the second contact C2 penetrating through the first etch stop layer 121, the first barrier layer 170, and the second interlayer insulating layer 112 in the vertical direction DR3 may be formed on the peripheral region III of the substrate 100. For example, a top surface of the second contact C2 may be formed on the same plane as (e.g., coplanar with) the top surface of the second interlayer insulating layer 112.

Next, the second etch stop layer 122 and the third interlayer insulating layer 113 may be sequentially formed on the top surface of the second interlayer insulating layer 112, the top surface of the first contact C1, and the top surface of the second contact C2, respectively. Next, the first wiring pattern 181 may be formed in each of the second etch stop layer 122 and the third interlayer insulating layer 113. For example, a top surface of the first wiring pattern 181 may be formed on the same plane as (e.g., coplanar with) a top surface of the third interlayer insulating layer 113. For example, some wirings of the first wiring pattern 181 may be connected to the first contact C1, and some other wirings of the first wiring pattern 181 may be connected to the second contact C2.

Referring to FIG. 2, the third etch stop layer 123 and the fourth interlayer insulating layer 114 may be sequentially formed on the top surface of the third interlayer insulating layer 113 and the top surface of the first wiring pattern 181, respectively. Next, the second wiring pattern 182 may be formed in each of the third etch stop layer 123 and the fourth interlayer insulating layer 114. For example, a top surface of the second wiring pattern 182 may be formed on the same plane as (e.g., coplanar with) a top surface of the fourth interlayer insulating layer 114. The second wiring pattern 182 may be connected to the first wiring pattern 181.

Next, the fourth etch stop layer 124 and the fifth interlayer insulating layer 115 may be sequentially formed on the top surface of the fourth interlayer insulating layer 114 and the top surface of the second wiring pattern 182, respectively. Next, the third wiring pattern 183 may be formed in each of the fourth etch stop layer 124 and the fifth interlayer insulating layer 115. Next, the fifth interlayer insulating layer 115 may be additionally formed to cover a top surface of the third wiring pattern 183. The third wiring pattern 183 may be connected to the second wiring pattern 182. In some other exemplary embodiments, after the third wiring pattern 183 is formed, the fifth interlayer insulating layer 115 may be formed to cover the third wiring pattern 183.

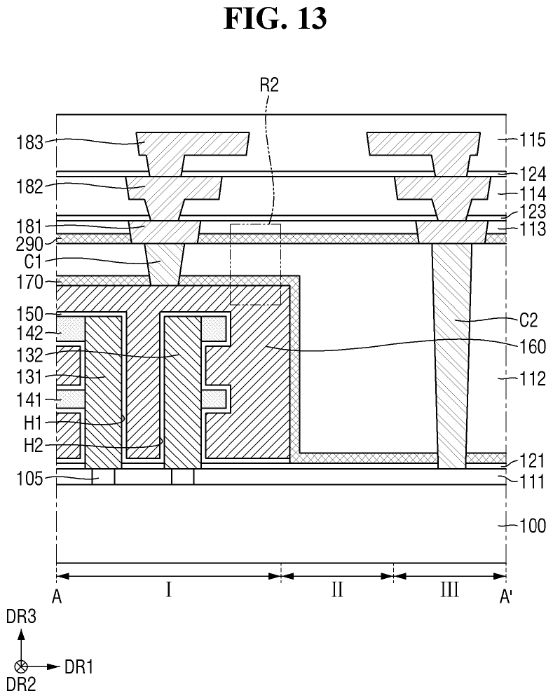

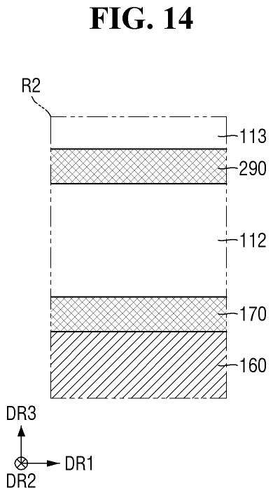

Hereinafter, a semiconductor device according to some other exemplary embodiments of the present disclosure will be described with reference to FIGS. 13 and 14. Differences from the semiconductor device illustrated in FIGS. 1 to 3 will be mainly described.

FIG. 13 is a cross-sectional view for describing a semiconductor device according to some other exemplary embodiments of the present disclosure. FIG. 14 is an enlarged view of region R2 of FIG. 13.

Referring to FIGS. 13 and 14, in a semiconductor device according to some other exemplary embodiments, a second barrier layer 290 may be disposed on the top surface of the second interlayer insulating layer 112.

The second barrier layer 290 may surround a sidewall of the first wiring pattern 181 on the top surface of the second interlayer insulating layer 112. The second barrier layer 290 may be in, e.g., direct, contact with the top surface of the second interlayer insulating layer 112. The second barrier layer 290 may be conformally formed. That is, the second barrier layer 290 may be formed with a uniform thickness.

The second barrier layer 290 may include at least one of metal oxide and metal nitride. For example, the second barrier layer 290 may include an aluminum (Al) element. For example, the second barrier layer 290 may include at least one of aluminum oxide (Al₂O₃) and aluminum nitride (AlN). In some other exemplary embodiments, the second barrier layer 290 may also include metal oxynitride. For example, the second barrier layer 290 may include aluminum oxynitride (AlON).

The third interlayer insulating layer 113 may be disposed on a top surface of the second barrier layer 290. The third interlayer insulating layer 113 may be in, e.g., direct, contact with the top surface of the second barrier layer 290. The third interlayer insulating layer 113 may surround the sidewall of the first wiring pattern 181. That is, the sidewall of the first wiring pattern 181 may be surrounded by each of the second barrier layer 290 and the third interlayer insulating layer 113.

The semiconductor device according to the present embodiment may prevent hydrogen ions present inside the second interlayer insulating layer 112 from directly moving into each of the third to fifth interlayer insulating layers 113, 114, and 115 by additionally disposing the second barrier layer 290 along the top surface of the second interlayer insulating layer 112. That is, by disposing the second barrier layer 290 along the top surface of the second interlayer insulating layer 112, the hydrogen ions present in the fifth interlayer insulating layer 115 may be effectively induced to move into the upper electrode 160 through the wiring patterns 181, 182, and 183 disposed on the second interlayer insulating layer 112. Accordingly, as deterioration of the wiring patterns 181, 182, and 183 is prevented, gate induced drain leakage (GIDL) characteristics may be improved.

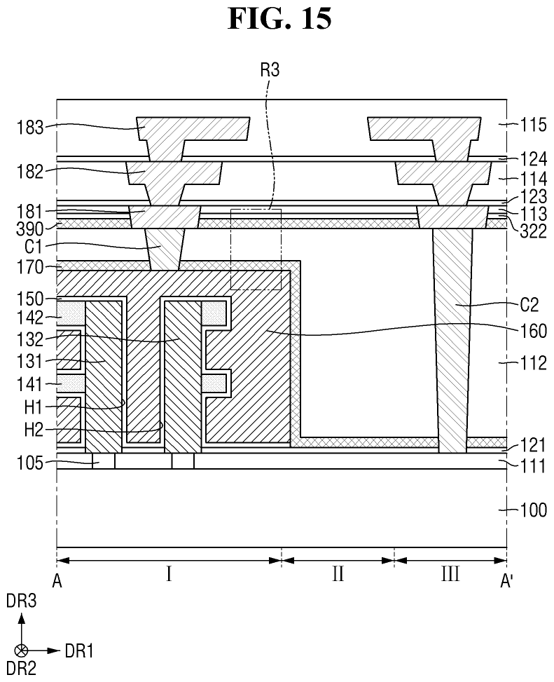

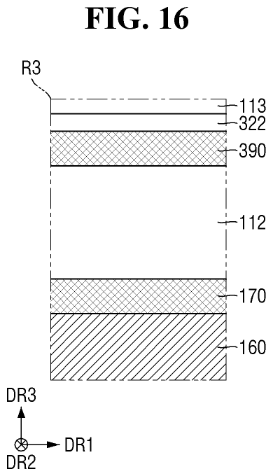

Hereinafter, a semiconductor device according to some still other exemplary embodiments of the present disclosure will be described with reference to FIGS. 15 and 16. Differences from the semiconductor device illustrated in FIGS. 1 to 3 will be mainly described.

FIG. 15 is a cross-sectional view for describing a semiconductor device according to some other exemplary embodiments. FIG. 16 is an enlarged view of region R3 of FIG. 15.

Referring to FIGS. 15 and 16, in a semiconductor device according to some other exemplary embodiments, a second barrier layer 390 and a second etch stop layer 322 may be sequentially disposed on the top surface of the second interlayer insulating layer 112.

The second barrier layer 390 may surround the sidewall of the first wiring pattern 181 on the second interlayer insulating layer 112. The second barrier layer 390 may be in, e.g., direct, contact with the top surface of the second interlayer insulating layer 112. The second barrier layer 390 may be conformally formed. That is, the second barrier layer 390 may be formed with a uniform thickness.

The second barrier layer 390 may include at least one of metal oxide and metal nitride. For example, the second barrier layer 390 may include an aluminum (Al) element. For example, the second barrier layer 390 may include at least one of aluminum oxide (Al₂O₃) and aluminum nitride (AlN). In some other exemplary embodiments, the second barrier layer 390 may also include metal oxynitride. For example, the second barrier layer 390 may include aluminum oxynitride (AlON).

The second etch stop layer 322 may surround the sidewall of the first wiring pattern 181 on a top surface of the second barrier layer 390. The second etch stop layer 322 may be in, e.g., direct, contact with the top surface of the second barrier layer 390. For example, the second etch stop layer 322 may be conformally formed. The second etch stop layer 322 may include a material different from that of the second barrier layer 390. The second etch stop layer 322 may include, e.g., at least one of silicon oxide, silicon nitride, silicon oxynitride, and a low-k material.

The third interlayer insulating layer 113 may be disposed on a top surface of the second etch stop layer 322. The third interlayer insulating layer 113 may be in, e.g., direct, contact with the top surface of the second etch stop layer 322. The third interlayer insulating layer 113 may surround the sidewall of the first wiring pattern 181. That is, the sidewall of the first wiring pattern 181 may be surrounded by each of the second barrier layer 390, the second etch stop layer 322, and the third interlayer insulating layer 113.

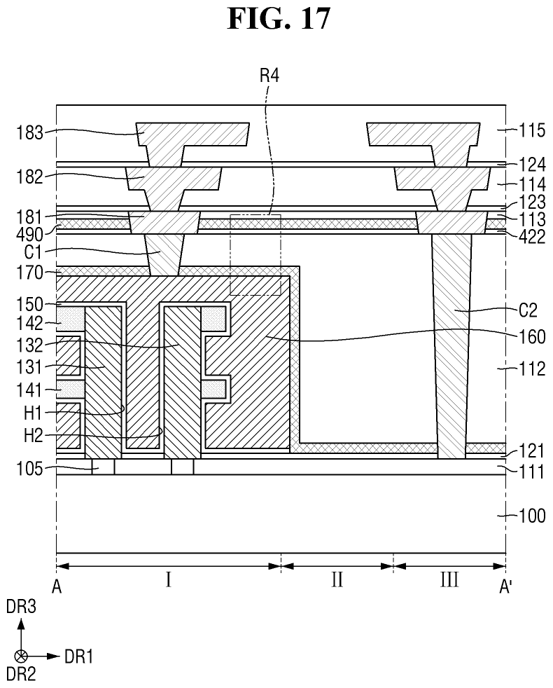

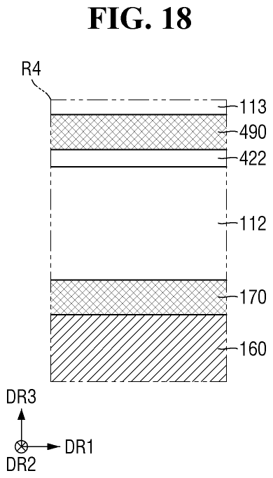

Hereinafter, a semiconductor device according to some other exemplary embodiments of the present disclosure will be described with reference to FIGS. 17 and 18. Differences from the semiconductor device illustrated in FIGS. 1 to 3 will be mainly described.

FIG. 17 is a cross-sectional view for describing a semiconductor device according to some other exemplary embodiments of the present disclosure. FIG. 18 is an enlarged view of region R4 of FIG. 17.

Referring to FIGS. 17 and 18, in a semiconductor device according to some other exemplary embodiments, a second etch stop layer 422 and a second barrier layer 490 may be sequentially disposed on the top surface of the second interlayer insulating layer 112.

The second etch stop layer 422 may surround the sidewall of the first wiring pattern 181 on the top surface of the second interlayer insulating layer 112. The second etch stop layer 422 may be in, e.g., direct, contact with the top surface of the second interlayer insulating layer 112. For example, the second etch stop layer 422 may be conformally formed. The second etch stop layer 422 may include, e.g., at least one of silicon oxide, silicon nitride, silicon oxynitride, and a low-k material.

The second barrier layer 490 may surround the sidewall of the first wiring pattern 181 on a top surface of the second etch stop layer 422. The second barrier layer 490 may be in, e.g., direct, contact with the top surface of the second etch stop layer 422. The second barrier layer 490 may be conformally formed. That is, the second barrier layer 490 may be formed with a uniform thickness.

The second barrier layer 490 may include a material different from that of the second etch stop layer 422. The second barrier layer 490 may include at least one of metal oxide and metal nitride. For example, the second barrier layer 490 may include an aluminum (Al) element. For example, the second barrier layer 490 may include at least one of aluminum oxide (Al₂O₃) and aluminum nitride (AlN). In some other exemplary embodiments, the second barrier layer 490 may also include metal oxynitride. For example, the second barrier layer 490 may include aluminum oxynitride (AlON).

The third interlayer insulating layer 113 may be disposed on a top surface of the second barrier layer 490. The third interlayer insulating layer 113 may be in, e.g., direct, contact with the top surface of the second barrier layer 490. The third interlayer insulating layer 113 may surround the sidewall of the first wiring pattern 181. That is, the sidewall of the first wiring pattern 181 may be surrounded by each of the second etch stop layer 422, the second barrier layer 490, and the third interlayer insulating layer 113.

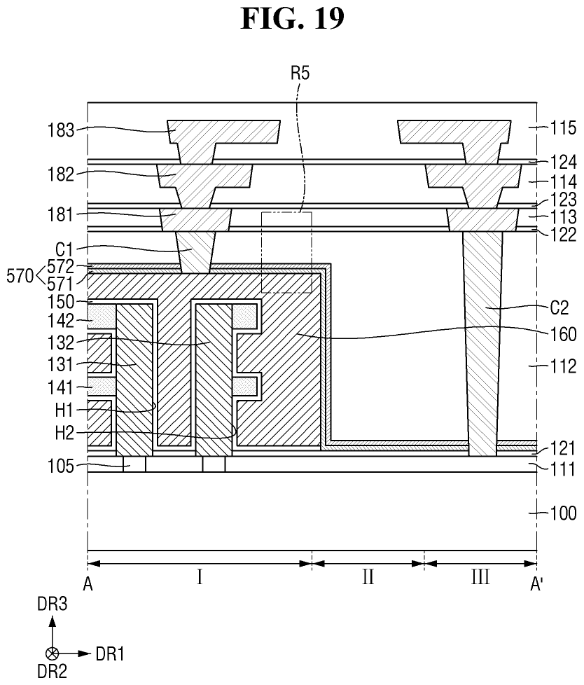

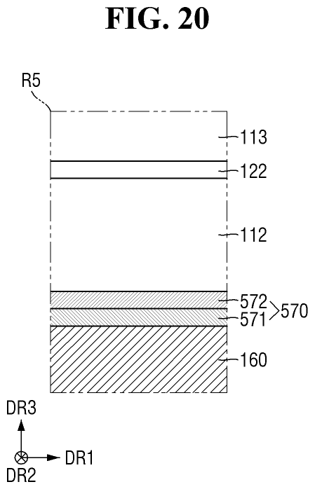

Hereinafter, a semiconductor device according to some other exemplary embodiments of the present disclosure will be described with reference to FIGS. 19 and 20. Differences from the semiconductor device illustrated in FIGS. 1 to 3 will be mainly described.

FIG. 19 is a cross-sectional view for describing a semiconductor device according to some other exemplary embodiments. FIG. 20 is an enlarged view of region R5 of FIG. 19.

Referring to FIGS. 19 and 20, in a semiconductor device according to some other exemplary embodiments of the present disclosure, a first barrier layer 570 may include a first sub-barrier layer 571 and a second sub-barrier layer 572.

The first sub-barrier layer 571 may be disposed along the sidewall and the top surface of the upper electrode 160. The first sub-barrier layer 571 may be in, e.g., direct, contact with the sidewall and the top surface of the upper electrode 160. In addition, the first sub-barrier layer 571 may be disposed along the top surface of the first etch stop layer 121 on each of the separation region II and the peripheral region III of the substrate 100. The first sub-barrier layer 571 may be in, e.g., direct, contact with the top surface of the first etch stop layer 121 on each of the separation region II and the peripheral region III of the substrate 100. For example, the first sub-barrier layer 571 may be conformally formed. The second sub-barrier layer 572 may be disposed on the first sub-barrier layer 571. The second sub-barrier layer 572 may be in, e.g., direct, contact with the first sub-barrier layer 571. For example, the second sub-barrier layer 572 may be conformally formed.

For example, the first sub-barrier layer 571 and the second sub-barrier layer 572 may include different materials. In some exemplary embodiments, the first sub-barrier layer 571 may include aluminum oxide (Al₂O₃), and the second sub-barrier layer 572 may include aluminum nitride (AlN). In some other exemplary embodiments, the first sub-barrier layer 571 may include aluminum nitride (AlN), and the second sub-barrier layer 572 may include aluminum oxide (Al₂O₃).

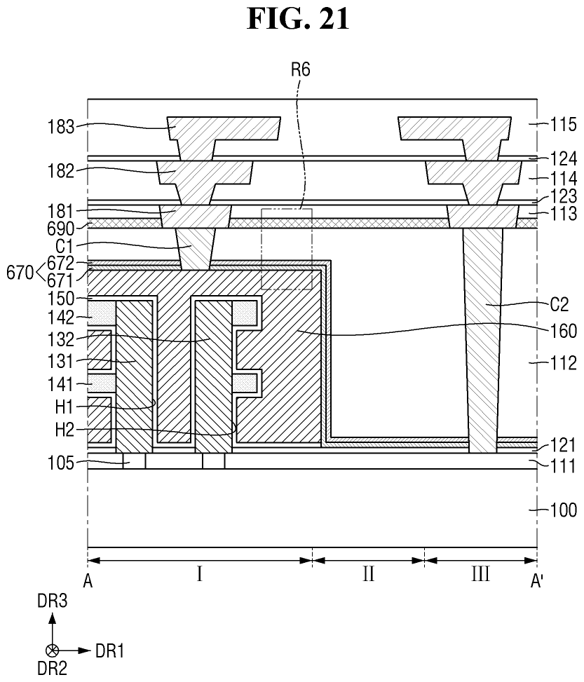

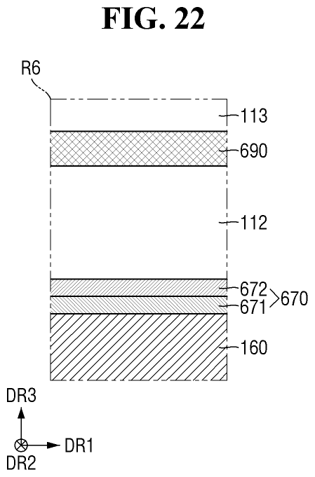

Hereinafter, a semiconductor device according to some other exemplary embodiments of the present disclosure will be described with reference to FIGS. 21 and 22. Differences from the semiconductor device illustrated in FIGS. 1 to 3 will be mainly described.

FIG. 21 is a cross-sectional view for describing a semiconductor device according to some other exemplary embodiments of the present disclosure. FIG. 22 is an enlarged view of region R6 of FIG. 21.

Referring to FIGS. 21 and 22, in a semiconductor device according to some other exemplary embodiments of the present disclosure, a first barrier layer 670 may include a first sub-barrier layer 671 and a second sub-barrier layer 672. In addition, a second barrier layer 690 may be disposed on the top surface of the second interlayer insulating layer 112.

The first sub-barrier layer 671 may be disposed along the sidewall and the top surface of the upper electrode 160. The first sub-barrier layer 671 may be in, e.g., direct, contact with the sidewall and the top surface of the upper electrode 160. In addition, the first sub-barrier layer 671 may be disposed along the top surface of the first etch stop layer 121 on each of the separation region II and the peripheral region III of the substrate 100. The first sub-barrier layer 671 may be in, e.g., direct, contact with the top surface of the first etch stop layer 121 on each of the separation region II and the peripheral region III of the substrate 100. For example, the first sub-barrier layer 671 may be conformally formed. The second sub-barrier layer 672 may be disposed on the first sub-barrier layer 671. The second sub-barrier layer 672 may be in, e.g., direct, contact with the first sub-barrier layer 671. For example, the second sub-barrier layer 672 may be conformally formed.

For example, the first sub-barrier layer 671 and the second sub-barrier layer 672 may include different materials. In some exemplary embodiments, the first sub-barrier layer 671 may include aluminum oxide (Al₂O₃), and the second sub-barrier layer 672 may include aluminum nitride (AlN). In some other exemplary embodiments, the first sub-barrier layer 671 may include aluminum nitride (AlN), and the second sub-barrier layer 672 may include aluminum oxide (Al₂O₃).

The second barrier layer 690 may surround the sidewall of the first wiring pattern 181 on the top surface of the second interlayer insulating layer 112. The second barrier layer 690 may be in, e.g., direct, contact with the top surface of the second interlayer insulating layer 112. The second barrier layer 690 may be conformally formed. That is, the second barrier layer 690 may be formed with a uniform thickness.

The second barrier layer 690 may include at least one of metal oxide and metal nitride. For example, the second barrier layer 690 may include an aluminum (Al) element. For example, the second barrier layer 690 may include at least one of aluminum oxide (Al₂O₃) and aluminum nitride (AlN). In some other exemplary embodiments, the second barrier layer 690 may also include metal oxynitride. For example, the second barrier layer 690 may include aluminum oxynitride (AlON).

The third interlayer insulating layer 113 may be disposed on a top surface of the second barrier layer 690. The third interlayer insulating layer 113 may be in, e.g., direct, contact with the top surface of the second barrier layer 690. The third interlayer insulating layer 113 may surround the sidewall of the first wiring pattern 181. That is, the sidewall of the first wiring pattern 181 may be surrounded by each of the second barrier layer 690 and the third interlayer insulating layer 113.

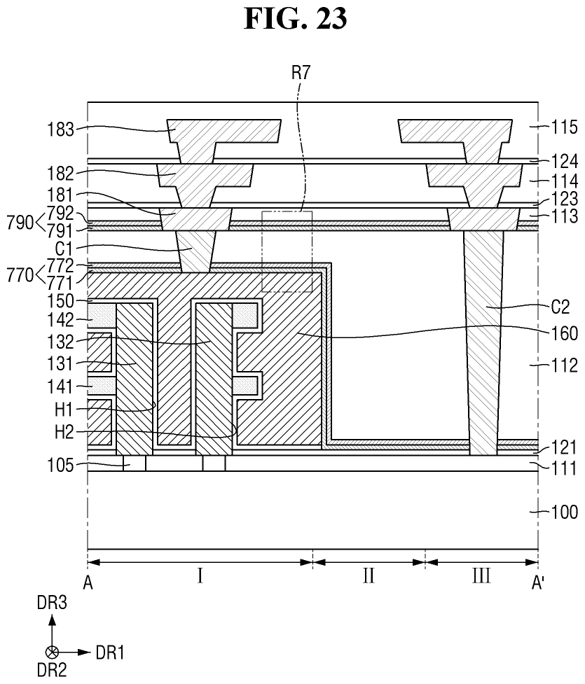

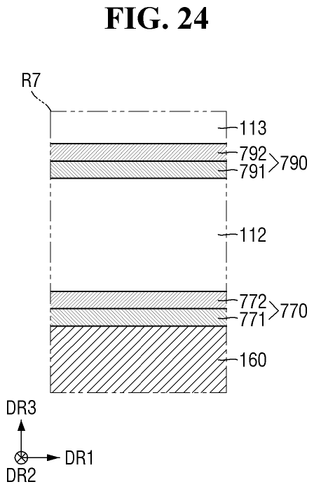

Hereinafter, a semiconductor device according to some other exemplary embodiments of the present disclosure will be described with reference to FIGS. 23 and 24. Differences from the semiconductor device illustrated in FIGS. 1 to 3 will be mainly described.

FIG. 23 is a cross-sectional view for describing a semiconductor device according to some other exemplary embodiments of the present disclosure. FIG. 24 is an enlarged view of region R7 of FIG. 23.

Referring to FIGS. 23 and 24, in a semiconductor device according to some other exemplary embodiments of the present disclosure, a first barrier layer 770 may include a first sub-barrier layer 771 and a second sub-barrier layer 772. In addition, a second barrier layer 790 may be disposed on the top surface of the second interlayer insulating layer 112. The second barrier layer 790 may include a third sub-barrier layer 791 and a fourth sub-barrier layer 792.

The first sub-barrier layer 771 may be disposed along the sidewall and the top surface of the upper electrode 160. The first sub-barrier layer 771 may be in, e.g., direct, contact with the sidewall and the top surface of the upper electrode 160. In addition, the first sub-barrier layer 771 may be disposed along the top surface of the first etch stop layer 121 on each of the separation region II and the peripheral region III of the substrate 100. The first sub-barrier layer 771 may be in, e.g., direct, contact with the top surface of the first etch stop layer 121 on each of the separation region II and the peripheral region III of the substrate 100. For example, the first sub-barrier layer 771 may be conformally formed. The second sub-barrier layer 772 may be disposed on the first sub-barrier layer 771. The second sub-barrier layer 772 may be in, e.g., direct, contact with the first sub-barrier layer 771. For example, the second sub-barrier layer 772 may be conformally formed.

For example, the first sub-barrier layer 771 and the second sub-barrier layer 772 may include different materials. In some exemplary embodiments, the first sub-barrier layer 771 may include aluminum oxide (Al₂O₃), and the second sub-barrier layer 772 may include aluminum nitride (AlN). In some other exemplary embodiments, the first sub-barrier layer 771 may include aluminum nitride (AlN), and the second sub-barrier layer 772 may include aluminum oxide (Al₂O₃).

The second barrier layer 790 may surround the sidewall of the first wiring pattern 181 on the top surface of the second interlayer insulating layer 112. The second barrier layer 790 may be in, e.g., direct, contact with the top surface of the second interlayer insulating layer 112. The second barrier layer 790 may be conformally formed. That is, the second barrier layer 790 may be formed with a uniform thickness. The second barrier layer 790 may include a third sub-barrier layer 791 and a fourth sub-barrier layer 792.

The third sub-barrier layer 791 may surround the sidewall of the first wiring pattern 181 on the top surface of the second interlayer insulating layer 112. The third sub-barrier layer 791 may be in, e.g., direct, contact with the top surface of the second interlayer insulating layer 112. For example, the third sub-barrier layer 791 may be conformally formed. The fourth sub-barrier layer 792 may be disposed on the third sub-barrier layer 791. The fourth sub-barrier layer 792 may be in, e.g., direct, contact with the third sub-barrier layer 791. For example, the fourth sub-barrier layer 792 may be conformally formed.

For example, the third sub-barrier layer 791 and the fourth sub-barrier layer 792 may include different materials. In some exemplary embodiments, the third sub-barrier layer 791 may include aluminum oxide (Al₂O₃), and the fourth sub-barrier layer 792 may include aluminum nitride (AlN). In some other exemplary embodiments, the third sub-barrier layer 791 may include aluminum nitride (AlN), and the fourth sub-barrier layer 792 may include aluminum oxide (Al₂O₃).

The third interlayer insulating layer 113 may be disposed on a top surface of the fourth sub-barrier layer 792. The third interlayer insulating layer 113 may be in, e.g., direct, contact with the top surface of the fourth sub-barrier layer 792. The third interlayer insulating layer 113 may surround the sidewall of the first wiring pattern 181. That is, the sidewall of the first wiring pattern 181 may be surrounded by each of the third sub-barrier layer 791, the fourth sub-barrier layer 792, and the third interlayer insulating layer 113.

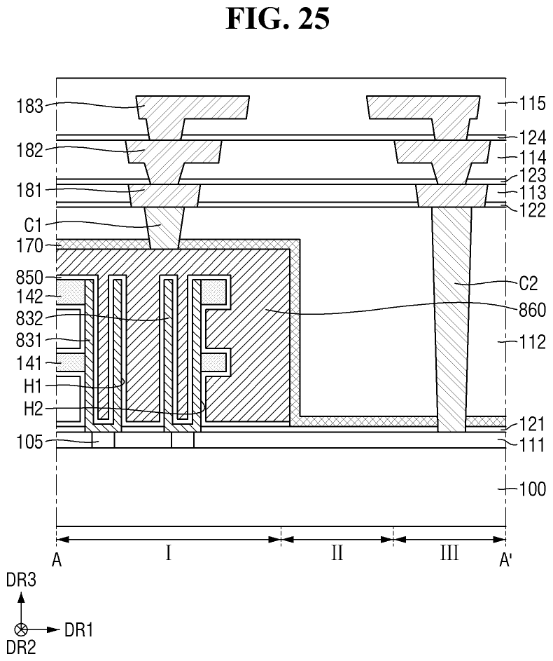

Hereinafter, a semiconductor device according to some other exemplary embodiments of the present disclosure will be described with reference to FIG. 25. Differences from the semiconductor device illustrated in FIGS. 1 to 3 will be mainly described.

FIG. 25 is a cross-sectional view for describing a semiconductor device according to some other exemplary embodiments.

Referring to FIG. 25, in a semiconductor device according to some other exemplary embodiments of the present disclosure, each of a first lower electrode 831 and a second lower electrode 832 may have a cylindrical shape.

A capacitor dielectric layer 850 may be conformally disposed along a surface of each of the first etch stop layer 121, the first supporter pattern 141, the second supporter pattern 142, the first lower electrode 831, and the second lower electrode 832 on the cell region I of the substrate 100. An upper electrode 860 may be disposed on the capacitor dielectric layer 150 on the cell region I of the substrate 100. For example, at least a portion of the upper electrode 860 may be surrounded by the first lower electrode 831. In addition, at least a portion of the upper electrode 860 may be surrounded by the second lower electrode 832.

By way of summation and review, aspects of the present disclosure provide a semiconductor device with improved gate induced drain leakage (GIDL) characteristics by preventing deterioration of wiring patterns.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate including a cell region and a peripheral region surrounding the cell region;
a lower electrode extending in a vertical direction on the cell region of the substrate;
an upper electrode surrounding a sidewall and a top surface of the lower electrode;
a capacitor dielectric layer between the lower electrode and the upper electrode;
a first barrier layer on the upper electrode, the first barrier layer being in contact with each of a sidewall and a top surface of the upper electrode;
a first interlayer insulating layer covering the first barrier layer, the first interlayer insulating layer including a material different from a material of the first barrier layer; and
a first contact penetrating through the first barrier layer and the first interlayer insulating layer in the vertical direction, the first contact being connected to the upper electrode.

2. The semiconductor device as claimed in claim 1, further comprising a first etch stop layer between the substrate and the first barrier layer, the first etch stop layer surrounding a portion of the sidewall of the lower electrode, and the first etch stop layer being in contact with the first barrier layer on the peripheral region of the substrate.

3. The semiconductor device as claimed in claim 1, wherein a top surface of the first interlayer insulating layer is on a same plane as a top surface of the first contact.

4. The semiconductor device as claimed in claim 1, wherein the first barrier layer includes at least one of aluminum oxide (Al₂O₃) and aluminum nitride (AlN).

5. The semiconductor device as claimed in claim 1, further comprising a second contact penetrating through the first barrier layer and the first interlayer insulating layer in the vertical direction on the peripheral region of the substrate, the second contact being spaced apart from the upper electrode in a horizontal direction.

6. The semiconductor device as claimed in claim 1, further comprising:
a first supporter pattern surrounding a portion of the sidewall of the lower electrode on the substrate; and
a second supporter pattern surrounding another portion of the sidewall of the lower electrode on the first supporter pattern.

7. The semiconductor device as claimed in claim 1, wherein the first barrier layer is conformal on the upper electrode.

8. The semiconductor device as claimed in claim 1, wherein the first barrier layer includes:
a first sub-barrier layer in contact with each of the sidewall and the top surface of the upper electrode, and
a second sub-barrier layer in contact with the first sub-barrier layer on the first sub-barrier layer, the second sub-barrier layer including a material different from a material of the first sub-barrier layer.

9. The semiconductor device as claimed in claim 1, further comprising:
a wiring pattern on the first contact;
a second barrier layer surrounding a sidewall of the wiring pattern on the first interlayer insulating layer; and
a second interlayer insulating layer surrounding the sidewall of the wiring pattern on the second barrier layer.

10. The semiconductor device as claimed in claim 9, wherein the second barrier layer includes at least one of aluminum oxide (Al₂O₃) and aluminum nitride (AlN).

11. The semiconductor device as claimed in claim 9, further comprising a second etch stop layer surrounding the sidewall of the wiring pattern between the second barrier layer and the second interlayer insulating layer, the second etch stop layer including a material different from a material of the second barrier layer.

12. The semiconductor device as claimed in claim 9, further comprising a second etch stop layer surrounding the sidewall of the wiring pattern between the first interlayer insulating layer and the second barrier layer, the second etch stop layer including a material different from a material of the second barrier layer.

13. The semiconductor device as claimed in claim 9, wherein the second barrier layer includes:
a third sub-barrier layer in contact with the first interlayer insulating layer; and
a fourth sub-barrier layer in contact with the third sub-barrier layer on the third sub-barrier layer, the fourth sub-barrier layer including a material different from a material of the third sub-barrier layer.

14. A semiconductor device, comprising:
a substrate including a cell region and a peripheral region surrounding the cell region;
a lower electrode extending in a vertical direction on the cell region of the substrate;
an upper electrode surrounding a sidewall and a top surface of the lower electrode;
a capacitor dielectric layer between the lower electrode and the upper electrode;
a first barrier layer on the upper electrode, the first barrier layer being in contact with each of a sidewall and a top surface of the upper electrode, the first barrier layer being conformal on the upper electrode, and the first barrier layer including an aluminum element; and
an etch stop layer between the substrate and the first barrier layer, the etch stop layer surrounding a portion of the sidewall of the lower electrode, and the etch stop layer being in contact with the first barrier layer on the peripheral region of the substrate.

15. The semiconductor device as claimed in claim 14, further comprising:
a first interlayer insulating layer covering the first barrier layer, the first interlayer insulating layer including a material different from a material of the first barrier layer; and
a first contact penetrating through the first barrier layer and the first interlayer insulating layer in the vertical direction, the first contact being connected to the upper electrode, and top surfaces of the first interlayer insulating layer and the first contact being coplanar.

16. The semiconductor device as claimed in claim 14, further comprising:
a first interlayer insulating layer covering the first barrier layer, the first interlayer insulating layer including a material different from a material of the first barrier layer; and
a second contact penetrating through the first barrier layer in the vertical direction on the peripheral region of the substrate, the second contact being spaced apart from the upper electrode in a horizontal direction.

17. The semiconductor device as claimed in claim 14, wherein the first barrier layer includes:
a first sub-barrier layer in contact with each of the sidewall and the top surface of the upper electrode, and
a second sub-barrier layer in contact with the first sub-barrier layer on the first sub-barrier layer, the second sub-barrier layer including a material different from a material of the first sub-barrier layer.

18. The semiconductor device as claimed in claim 14, further comprising:
a first interlayer insulating layer covering the first barrier layer, the first interlayer insulating layer including a material different from a material of the first barrier layer;
a wiring pattern on the first interlayer insulating layer;
a second barrier layer surrounding a sidewall of the wiring pattern on the first interlayer insulating layer, the second barrier layer including at least one of aluminum oxide (Al₂O₃) and aluminum nitride (AlN); and
a second interlayer insulating layer surrounding the sidewall of the wiring pattern on the second barrier layer.

19. A semiconductor device, comprising:
a substrate including a cell region and a peripheral region surrounding the cell region;
a lower electrode extending in a vertical direction on the cell region of the substrate;
an upper electrode surrounding a sidewall and a top surface of the lower electrode;
a capacitor dielectric layer between the lower electrode and the upper electrode;
a first barrier layer on the upper electrode, the first barrier layer being in contact with each of a sidewall and a top surface of the upper electrode, the first barrier layer being conformally on the upper electrode, and the first barrier layer including at least one of aluminum oxide (Al₂O₃) and aluminum nitride (AlN);
a first interlayer insulating layer covering the first barrier layer, the first interlayer insulating layer including a material different from a material of the first barrier layer;
an etch stop layer between the substrate and the first barrier layer, the etch stop layer surrounding a portion of the sidewall of the lower electrode, and the etch stop layer being in contact with the first barrier layer on the peripheral region of the substrate;
a first contact penetrating through the first barrier layer and the first interlayer insulating layer in the vertical direction, the first contact being connected to the upper electrode; and
a second contact penetrating through the first barrier layer and the first interlayer insulating layer in the vertical direction on the peripheral region of the substrate, the second contact being spaced apart from the upper electrode in a horizontal direction, and top surfaces of the first interlayer insulating layer, the first contact, and the second contact being coplanar with each other.

20. The semiconductor device as claimed in claim 19, further comprising:
a wiring pattern on the first interlayer insulating layer;
a second barrier layer surrounding a sidewall of the wiring pattern on the first interlayer insulating layer, the second barrier layer including at least one of aluminum oxide (Al₂O₃) and aluminum nitride (AlN); and
a second interlayer insulating layer surrounding the sidewall of the wiring patterns on the second barrier layer.
